(19) United States
(12) Patent Application Publication
(10) Pub. No.: US 2003/0008430 A1
(43) Pub. Date: Jan. 9, 2003

(54) Fabrication method of semiconductor light-emitting device

(75) Inventors: Junichi Nakamura, Kashiba-shi (JP); Kazuaki Sasaki, Osaka-shi (JP)

Correspondence Address: Barry E. Bretschneider, Morrison & Foerster LLP, Suite 300, 1650 Tyson Blvd, McLean, VA, 22102, US

(73) Assignee: SHARP KABUSHIKI KAISHA, Osaka (JP)

(21) Appl. No.: 10/189,627

(22) Filed: Jul. 8, 2002

(30) Foreign Application Priority Data
Jul. 6, 2001 (JP) 2001-206136

(51) Int. Cl. H01L 21/00

(52) U.S. Cl. 438/47; 438/46; 438/37

(57) ABSTRACT

With use of MOCVD method, there are grown in sequence on an n-type GaAs substrate 11, an n-type lower clad 12, an active layer 13, and a p-type upper cladding layer 14 to constitute a light emitting portion. On top of the light emitting portion, there are grown in sequence a p-type intermediate layer 15 and a p-type current diffusion layer 16 made of AlGaInP semiconductor. The intermediate layer 15 made of AlGaInP semiconductor is provided with a growth rate of 1 μm/h or less and a lattice match ratio Δa/a against GaAs of −3.2% or more and −2.5% or less. A V/III ratio of the intermediate layer 15 in growth and a V/III ratio of the current diffusion layer 16 in growth are so set that a number of crystal defects observed on the crystal surface is 20 or less per semiconductor light-emitting device. Thus-fabricated semiconductor light-emitting device is high in intensity and small in power consumption, and enables enhancement of productivity.

### BACKGROUND OF THE INVENTION

The present invention relates to a fabrication method of a semiconductor light-emitting device having a light emitting portion formed on a compound semiconductor substrate.

For forming high-intensity semiconductor light-emitting devices, it is important to increase current injection to a light emitting portion and to implement effective extraction of light to the outside of a device, as well as to increase light emitting efficiency. Accordingly, it is effective to use a current diffusion layer for increasing current injection to the light emitting portion and an intermediate layer capable of increasing current injection without raising operating voltage. The current diffusion layer is also effective for implementing effective extraction of light to the outside of the device.

Conventionally, there has been a semiconductor light-emitting device disclosed in Japanese Patent Laid-Open Publication No. HEI 09-260724. This semiconductor light-emitting device is, as shown in FIG. 19, formed from an n-type GaAs substrate 211, on which there are laminated an n-type AlGaInP cladding layer 212, an AlGaInP active layer 213, and a p-type AlGaInP cladding layer 214, further on which a p-type AlGaInP intermediate layer 215 and a p-type GaP current diffusion layer 216 are laminated. Further, a p-type electrode 217 is formed by deposition on the p-type GaP current diffusion layer 216, and an n-type electrode 218 is formed by deposition under the n-type GaAs substrate 211. The p-type AlGaInP intermediate layer 215 has a composition selected so that a lattice match ratio is between that of the p-type AlGaInP cladding layer 214 and the p-type GaP current diffusion layer 216, and a hetero barrier in the energy-band profile is decreased by setting a conduction band lower edge to be between a conduction band lower edge of the upper cladding layer and a conduction band lower edge of the current diffusion layer, and by setting a valence band upper edge to be between a valence band upper edge of the upper cladding layer and a valence band upper edge of the current diffusion layer in the energy position prior to effecting an junction.

Since this conventional semiconductor light-emitting device has the p-type GaP current diffusion layer 216, current may be injected not only to right under the p-type electrode 217, but also to the entire active layer 213.

FIG. 20 shows the energy-band profile in the upper cladding layer to the current diffusion layer without use of the intermediate layer, and FIG. 21 shows the energy-band profile in the upper cladding layer to the current diffusion layer with use of the intermediate layer. Since the semiconductor light-emitting device has the p-type AlGaInP intermediate layer 215, energy discontinuity may be divided and reduced as shown in FIG. 21 compared to the energy discontinuity in the energy-band profile without use of the intermediate layer shown in FIG. 20, which makes it possible to lower a hetero barrier generated in an interface between the p-type AlGaInP cladding layer 214 and the p-type GaP current diffusion layer 216. In addition, the semiconductor light-emitting device is given a composition in which a lattice constant of the p-type AlGaInP intermediate layer 215 is 5.55 Å, which is between 5.65 Å, a lattice constant of the p-type AlGaInP cladding layer 214 and 5.45 Å, a lattice constant of the p-type GaP current diffusion layer 216, for alleviating lattice mismatch. This enables decrease of an interface state generated in an interface between the cladding layer 214 and the current diffusion layer 216, and therefore a curve of the energy-band profile generated by the interface state may be reduced, thereby helping reduction of an energy barrier in the interface. The effect of reducing the energy barrier leads to considerable reduction of operating voltage.

In the above semiconductor light-emitting device, the cladding layer 214 is composed of AlGaInP having a lattice constant of 5.65 Å, the intermediate layer 215 is composed of AlGaInP having a lattice constant of 5.55 Å, and the current diffusion layer 216 is composed of GaP having a lattice constant of 5.45 Å, for alleviating lattice mismatch. However, in between the p-type AlGaInP cladding layer 214 and the p-type AlGaInP intermediate layer 215, and between the p-type AlGaInP intermediate layer 215 and the p-type GaP current diffusion layer 216, there is still a large lattice mismatch as shown by a lattice match ratio Δa/a of approx. −1.8%. With such a large lattice mismatch, it is difficult to grow layers with good crystallinity above the interface having a lattice mismatch, and a number of crystal defects such as cross hatching and hillock are generated.

Accordingly, in order to solve such a problem, a solution is proposed in a fabrication method of a semiconductor light-emitting device disclosed in Japanese Patent Laid-Open Publication No. 2000-216430. In the fabrication method of a semiconductor light-emitting device, the semiconductor light-emitting device has a structure and an energy-band profile identical to those of the semiconductor light-emitting device disclosed in Japanese Patent Laid-Open Publication No. HEI 09-260724. However, a growth rate of the intermediate layer and the current diffusion layer in an early stage of growth is set to be 1 μm/h or less and a mismatch value in the intermediate layer is specified, which fulfils considerable reduction of crystal defects such as cross hatching and hillock.

The fabrication method of a semiconductor light-emitting device implements reduction of operating voltage by setting a conduction band lower edge and a valence band upper edge of the intermediate layer to be in between those of the cladding layer and the current diffusion layer in relation to energy position prior to conjunction, and further decreases an interface state by setting a lattice constant of the intermediate layer in between that of the upper cladding layer and the current diffusion layer, thereby implementing further reduction of operating voltage. Further, by setting a growth rate of the intermediate layer and the current diffusion layer to be 1 μm/h as well as specifying a mismatch value of the intermediate layer, crystal defects on the crystal surface may be decreased.

However, an applicant of the present invention has found out by an experiment that in a growing process of layers having a lattice mismatch such as intermediate layers, current diffusion layers, and current blocking layers, effects of reducing operating voltage and reducing crystal defects are not sufficient depending on V/III ratio, that is a ratio of a molar flow rate of feeding V-group material gas and a molar flow rate of feeding III-group material gas in the growing process.

As a result, the fabrication method of a semiconductor light-emitting device suffers a problem that current diffusion and light transmittance in the current diffusion layer are degraded, and therefore light extraction efficiency and current injection efficiency are decreased, which disables obtainment of enough intensity, as well as suffers a problem that insufficient reduction of operating voltage prevents sufficient reduction of power consumption. Further in the fabrication method of a semiconductor light-emitting device, crystal defects on the crystal surface damages adherence of an electrode formed on the current diffusion layer, which causes exfoliation of the electrode, thereby leading to decreased production yield and reduced productivity.

### SUMMARY OF THE INVENTION

Accordingly, it is an object of the present invention to provide a fabrication method of a semiconductor device with high intensity, low power consumption, and good productivity.

In order to achieve the above object, there is provided a fabrication method of a semiconductor light-emitting device having a light emitting portion composed of at least a lower cladding layer, an active layer, and an upper cladding layer formed on a compound semiconductor substrate, and a layer to be grown above the light emitting portion, characterized in that

lattice mismatch with 0.25% or more absolute value of a lattice match ratio Δa/a is present in between a layer grown above the light emitting portion and a layer grown right under the light emitting layer, and at least at a growth starting time of the layer to be grown above the light emitting portion, a V/III ratio that is a ratio of a molar flow rate of feeding V-group material gas to a molar flow rate of feeding III-group material gas is so set that a number of crystal defects observed on a crystal surface at an end of growth of all crystals in the semiconductor light-emitting device is to be 20 or less per semiconductor light-emitting device.

According to the fabrication method of a semiconductor light-emitting device, at least at a growth starting time of a layer to be grown above the light emitting portion, a V/III ratio that is a ratio of a molar flow rate of feeding V-group material gas to a molar flow rate of feeding III-group material gas is so set that a number of crystal defects on the crystal surface at the end of crystal growth to be 20 or less per semiconductor light-emitting device. This improves crystallinity of the layer to be grown above the light emitting portion even under a condition of easily generating crystal defects, the condition in which the absolute value of a lattice match ratio Δa/a is 0.25% or more. Consequently, crystallinity of a layer to be grown above the light emitting portion, e.g. a current diffusion layer, is improved, which leads to improvement of light extraction efficiency and current injection efficiency, as well as to decrease of crystal defects on the crystal surface after growth of all the crystals of the semiconductor light-emitting device. This increases adherence of an electrode formed thereon, thereby increasing production yield. Thus, high-intensity semiconductor light-emitting devices with good production yield may be fabricated. It is noted that relation between a lattice match ratio and a crystal defect was experimentally examined. The result indicates that 0.25% or more absolute value of a lattice match ratio Δa/a is a condition of generating a crystal defect (hatching).

In one embodiment of the present invention, the layer to be grown above the light emitting portion includes an intermediate layer for alleviating at least either lattice mismatch or energy discontinuity between a layer to be grown further above and the light emitting portion.

According to the fabrication method of a semiconductor light-emitting device in the above embodiment, lattice mismatch between a layer to be grown on the intermediate layer and the light emitting portion is alleviated by the intermediate layer, which makes it possible to decrease crystal defects on the crystal surface, thereby improving adherence of an electrode and increasing production yield. In addition, energy discontinuity between a layer to be grown on the intermediate layer and the light emitting portion is alleviated by the intermediate layer, which enables reduction of operating voltage, resulting in decrease of power consumption.

In one embodiment of the present invention, the layer to be grown above the light emitting portion includes at least either a current diffusion layer or a current blocking layer.

According to the fabrication method of a semiconductor light-emitting device in the above embodiment, the current diffusion layer with good crystallinity helps to enhance an effect of current diffusion, and the current blocking layer with good crystallinity help to enhance an effect of current blocking.

In one embodiment of the present invention, the compound semiconductor substrate is composed of GaAs, and

the lower cladding layer, the active layer, the upper cladding layer, and the layer to be grown above the light emitting portion are composed of (AlₓGa₁₋ₓ) _{y}In_{1-y}P (0≦x≦1, 0≦y≦1) semiconductor.

According to the fabrication method of a semiconductor light-emitting device in the above embodiment, the AlGaInP semiconductor light-emitting device improves crystallinity of the layer to be grown above the light emitting portion. This increases light extraction efficiency and current injection efficiency, as well as reduces crystal defects on the crystal surface, thereby bringing about good adherence of an electrode and increased production yield.

Also, there is provided a fabrication method of a semiconductor light-emitting device having a light emitting portion composed of at least a lower cladding layer, an active layer, and an upper cladding layer formed on a compound semiconductor substrate,

an intermediate layer to be grown on the upper cladding layer in the light emitting portion, and

at least either a current diffusion layer or a current blocking layer to be grown on the intermediate layer,

the intermediate layer alleviating at least either lattice mismatch or energy discontinuity between the current diffusion layer and the light emitting portion or between the current blocking layer and the light emitting portion, characterized in that

the lower cladding layer, the active layer, the upper cladding layer, and the intermediate layer are composed of (AlₓGa₁₋ₓ) _{y}In_{1-y}P (0≦x≦1, 0≦y≦1) semiconductor,

the current diffusion layer or the current blocking layer are composed of (AlₓGa₁₋ₓ) _{y}In_{1-y}P (0≦x≦1, 0≦y≦1) semiconductor, and

at least at a growth starting time in growing the intermediate layer on the upper cladding layer with presence of lattice mismatch against the upper cladding layer with 0.25% or more absolute value of a lattice match ratio Δa/a, a V/III ratio that is a ratio of a molar flow rate of feeding V-group material gas to a molar flow rate of feeding III-group material gas is set to be 300 or more.

According to the fabrication method of a semiconductor light-emitting device, at least at a growth starting time in growing the intermediate layer with presence of lattice mismatch against the upper cladding layer with 0.25% or more absolute value of a lattice match ratio Δa/a, a V/III ratio is set to be 300 or more, which improves crystallinity of the intermediate layer even under a condition of easily generating crystal defects, the condition in which an absolute value of the lattice match ratio Δa/a is 0.25% or more. Consequently, crystallinity of the current diffusion layer or the current blocking layer to be grown on the intermediate layer is improved, which helps to enhance light extraction efficiency and current injection efficiency, as well as to decrease crystal defects on the crystal surface after crystal growth. This increases adherence of an electrode, thereby improving production yield.

Also, there is provided a fabrication method of a semiconductor light-emitting device having a light emitting portion composed of at least a lower cladding layer, an active layer, and an upper cladding layer formed on a compound semiconductor substrate,

an intermediate layer to be grown on the upper cladding layer in the light emitting portion, and

at least either a current diffusion layer or a current blocking layer to be grown on the intermediate layer,

the intermediate layer alleviating at least either lattice mismatch or energy discontinuity between the current diffusion layer and the light emitting portion or between the current blocking layer and the light emitting portion, characterized in that

the lower cladding layer, the active layer, the upper cladding layer, and the intermediate layer are composed of (AlₓGa₁₋ₓ) _{y}In_{1-y}P (0≦x≦1, 0≦y≦1) semiconductor,

the current diffusion layer or the current blocking layer is composed of (AlₓGa₁₋ₓ) _{y}In_{1-y}P (0≦x≦1, 0≦y≦1) semiconductor, and

in growing the current diffusion layer or the current blocking layer on the intermediate layer with presence of lattice mismatch against the intermediate layer with 0.25% or more absolute value of a lattice match ratio Δa/a, a V/III ratio that is a ratio of a molar flow rate of feeding V-group material gas to a molar flow rate of feeding III-group material gas at least at a growth starting time of the current diffusion layer or the current blocking layer is set to be 200 or more.

According to the fabrication method of a semiconductor light-emitting device, in growing the current diffusion layer or the current blocking layer on the intermediate layer with presence of lattice mismatch against the intermediate layer with 0.25% or more absolute value of a lattice match ratio Δa/a, a V/III ratio at least at a growth starting time of the current diffusion layer or the current blocking layer is set to be 200 or more. Consequently, crystallinity of the current diffusion layer or the current blocking layer is improved in a condition of easily generating crystal defects, the condition in which an absolute value of the lattice match ratio Δa/a is 0.25% or more. This enhances light extraction efficiency and current injection efficiency, as well as reduces crystal defects on the crystal surface, thereby bringing about good adherence of an electrode and increased production yield.

In one embodiment of the present invention, during growth after a growth starting time in a growing process of the layer to be grown above the light emitting portion, a V/III ratio that is a ratio of a molar flow rate of feeding V-group material gas to a molar flow rate of feeding III-group material gas is set to be smaller than that at the growth starting time.

According to the fabrication method of a semiconductor light-emitting device in the above embodiment, during growth after a growth starting time in the growing process of the layer to be grown above the light emitting portion, a V/III ratio that is a ratio of a molar flow rate of feeding V-group material gas to a molar flow rate of feeding III-group material gas is set to be smaller than that at the growth starting time. This helps to improve crystallinity of the layer to be grown above the light emitting portion and adherence of the electrode, as well as to minimize increase in consumption of materials for implementing cost reduction.

In one embodiment of the present invention, a growth rate at least at a growth starting time of the layer to be grown above the light emitting portion is 1 am/h or less.

According to the fabrication method of a semiconductor light-emitting device in the above embodiment, a growth rate at least at a growth starting time of the layer to be grown above the light emitting portion is 1 μm/h or less. This makes it possible to reduce crystal defects mainly generated at least at the growth starting time of the layer to be grown above the light emitting portion, which enhances crystallinity of the layer to be grown above the light emitting portion and decreases crystal defects on the crystal surface after crystal growth.

In one embodiment of the present invention, the intermediate layer is composed of AlGaInP semiconductor having a lattice match ratio Δa/a against GaAs of −3.2% or more and −2.5% or less.

According to the fabrication method of a semiconductor light-emitting device in the above embodiment, when the lattice match ratio Δa/a of the intermediate layer against GaAs is −2.5% or less, a number of crystal defects on the crystal surface may be reduced to 20 or less, whereas when the lattice match ratio Δa/a is −3.2% or more, a rise of operating voltage in an interface of the intermediate layer with driving current of 20 mA may be constrained to 0.5V or less. This helps to enhance crystallinity of the intermediate layer, and improves adherence of the electrode and production yield. In addition, low voltage operation is implemented, thereby enabling reduction of power consumption.

In one embodiment of the present invention, a growth temperature of the layer to be grown above the light emitting portion is higher than a growth temperature of the active layer.

According to the fabrication method of a semiconductor light-emitting device in the above embodiment, a growth temperature of the layer to be grown above the light emitting portion is higher than a growth temperature of the active layer. This enables further increase of the crystallinity of the layer to be grown above the light emitting portion and further improvement of adherence of an electrode, as well as enhancement of production yield.

In one embodiment of the present invention, MOCVD (metal-organic chemical vapor deposition) method is used to grow the lower cladding layer, the active layer, the upper cladding layer, and the layer to be grown above the light emitting portion.

According to the fabrication method of a semiconductor light-emitting device in the above embodiment, the semiconductor light-emitting device is fabricated by the crystal growth method, which facilitates fabrication of semiconductor light-emitting devices having high intensity and high productivity and enabling low voltage operation.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a cross sectional view showing a light emitting diode fabricated by a fabrication method of a semiconductor light-emitting device in a first embodiment of the present invention;

FIG. 2 is a view showing relation between a V/III ratio of an intermediate layer of the light emitting diode and a number of crystal defects on the crystal surface when a V/III ratio of a current diffusion layer is 500;

FIG. 3 is a view showing relation between a V/III ratio of a current diffusion layer of the light emitting diode and a number of crystal defects on the crystal surface when a V/III ratio of an intermediate layer is 500;

FIG. 4 is a cross sectional view showing a light emitting diode fabricated by a fabrication method of a semiconductor light-emitting device in a second embodiment of the present invention;

FIG. 5 is a view showing a V/III ratio setting value during growth of an intermediate layer of the light emitting diode;

FIG. 6 is a cross sectional view showing a light emitting diode fabricated by a fabrication method of a semiconductor light-emitting device in a third embodiment of the present invention;

FIG. 7 is a view showing a V/III ratio setting value during growth of an intermediate layer of the light emitting diode;

FIG. 8 is a cross sectional view showing a light emitting diode fabricated by a fabrication method of a semiconductor light-emitting device in a fourth embodiment of the present invention;

FIG. 9 is a view showing a growth rate of each layer of the light emitting diode;

FIG. 10 is a cross sectional view showing the light emitting diode under fabrication;

FIG. 11 is a cross sectional view showing the light emitting diode in a completed state;

FIG. 12 is a view showing a V/III ratio setting value during growth of an intermediate layer and a current diffusion layer of the light emitting diode;

FIG. 13 is a cross sectional view showing a light emitting diode fabricated by a fabrication method of a semiconductor light-emitting device in a fifth embodiment of the present invention;

FIG. 14 is a view showing a growth rate of each layer of the light emitting diode;

FIG. 15 is a cross sectional view showing the light emitting diode with a current blocking layer etched in a round shape;

FIG. 16 is a cross sectional view of the light emitting diode in a completed state;

FIG. 17 is a view showing transition of a growth temperature of each layer of the light emitting diode;

FIG. 18 is a view showing setting of a V/III ratio during growth of an intermediate layer and a current diffusion layer;

FIG. 19 is a cross sectional view showing a conventional semiconductor light-emitting device;

FIG. 20 is a view showing the energy-band profile of a semiconductor light-emitting device without use of an intermediate layer between an upper cladding layer and a current diffusion layer; and

FIG. 21 is a view showing the energy-band profile of a semiconductor light-emitting device with use of an intermediate layer between an upper cladding layer and a current diffusion layer.

### DETAILED DESCRIPTION OF THE PREFERRED EMBODIMENTS

The fabrication method of a semiconductor lightemitting device of the present invention will be described hereinbelow in detail in conjunction with the embodiment with reference to accompanying drawings.

(First Embodiment)

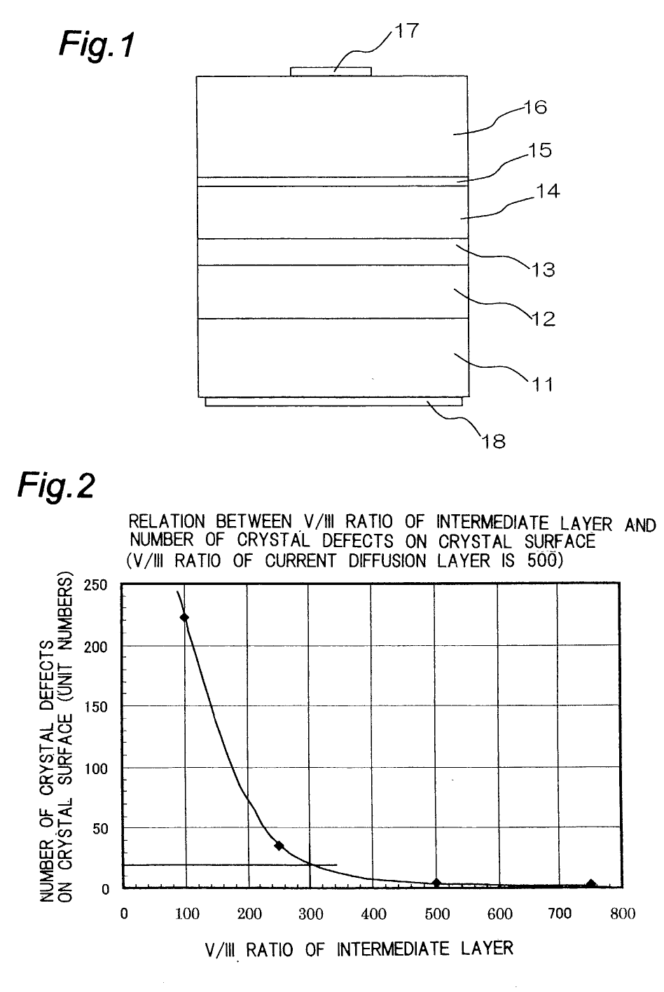

FIG. 1 is a cross sectional view showing a light emitting diode fabricated by a fabrication method of a semiconductor light-emitting device in a first embodiment of the present invention.

As shown in FIG. 1, there are grown in sequence on an n-type GaAs substrate 11, an n-type (AlₓGa₁₋ₓ) _{0.51}In_{0.49}P (0≦x≦1) lower cladding layer 12 (e.g. x=1.0, Si carrier density of 5×10¹⁷cm⁻³, thickness of 1.0 μm), (AlₓGa₁₋ₓ) _{0.51}In_{0.49}P (0≦x≦1) active layer 13 (e.g. x=0.3, thickness of 0.5 μm), and a p-type (AlₓGa₁₋ₓ) _{0.51}In_{0.49}P (0≦x≦1) upper cladding layer 14 (e.g. x=1.0, Zn carrier density of 5×10¹⁷cm⁻³, thickness of 1.0 μm) at a growth rate of approx. 1 to 2.5 μm/h with use of metal-organic chemical vapor deposition (MOCVD) method. The lower cladding layer 12, the active layer 13, and the upper cladding layer 14 constitute a light emitting portion.

Further on top of the light emitting portion, there are grown a p-type (AlₓGa₁₋ₓ) _{y}In_{1-y}P (0≦x≦1, 0≦y≦1) intermediate layer 15 (e.g. x=0.4, y=0.9 (lattice match ratio Δa/a against GaAs of approx. −2.8%), Zn carrier density of 1×10¹⁸cm⁻³, thickness of 0.1 μm, growth rate of 0.9 μm/h, V/III ratio in growth of 500), and a p-type (AlₓGa₁₋ₓ) _{y}In_{1-y}P (0≦x≦1, 0≦y≦1) current diffusion layer 16 (e.g. x=0.0, y=1.0, Zn carrier density of 3×10¹⁸cm⁻³, thickness of 7.0 μm, V/III ratio in growth of 300) with use of metal-organic chemical vapor deposition method. The growth temperature thereof is approx. 730° C.

Next, a p-type electrode 17 (e.g. Au—Zn) is formed on the current diffusion layer 16 by deposition, and an n-type electrode 18 (e.g. Au—Ge) is formed under the n-type GaAs substrate 11 by deposition. Then the p-type electrode 17 is processed to be for example in a round shape, by which a light emitting diode is completed.

In the fabrication method of a semiconductor light-emitting device of the first embodiment, the intermediate layer 15 has a growth rate of 0.9 μm/h and a lattice match ratio Δa/a against GaAs of −2.8% (satisfying the condition of a growth rate of 1 μm/h or less and the condition of a lattice match ratio Δa/a of −3.2% or more and −2.5% or less). However, satisfying these conditions is not enough for sufficient reduction of a number of crystal defects observed on the crystal surface.

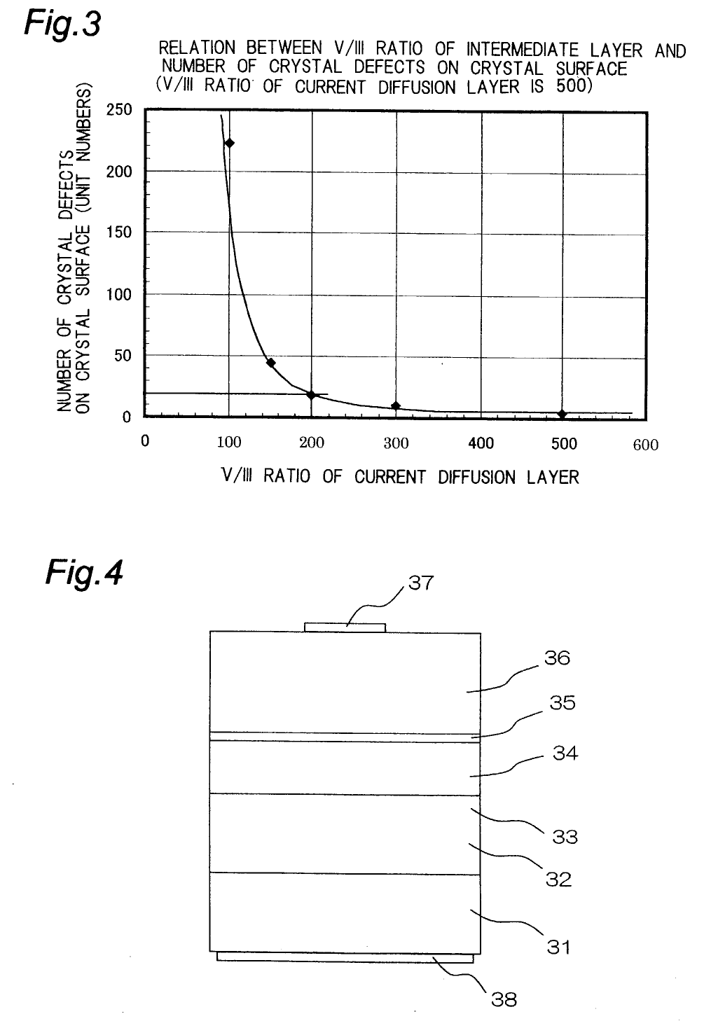

Accordingly, in the fabrication method of a semiconductor light-emitting device of the first embodiment, there was conducted in advance an experiment of determining relation between a crystal defect observed on the crystal surface and a V/III ratio that is a ratio of a molar flow rate of feeding V-group material gas to a molar flow rate of feeding III-group material gas. In the experiment, a light emitting diode was fabricated by the fabrication method of a semiconductor light-emitting device with the V/III ratio in growing an intermediate layer and a current diffusion layer being controlled by changing a flow rate of PH₃, a V-group material gas. In each V/III ratio of the intermediate layer and the current diffusion layer, a number of crystal defects observed on the crystal surface after crystal growth was counted. FIGS. 2 and 3 show the result of the experiment. More particularly, FIG. 2 shows relation between the V/III ratio of the intermediate layer and a number of crystal defects on the crystal surface when the V/III ratio of the current diffusion layer is 500, while FIG. 3 shows relation between the V/III ratio of the current diffusion layer and a number of crystal defects on the crystal surface when the V/III ratio of the intermediate layer is 500.

As shown in FIG. 2, in the area where the V/III ratio of the intermediate layer is 300 or larger, a number of crystal defects observed on the crystal surface is 20 or less per semiconductor light-emitting device. However, this is the result when the V/III ratio of the current diffusion layer is 500, and therefore a number of the crystal defects is not sufficiently reduced depending on the V/III ratio of the current diffusion layer. Accordingly, a number of crystal defects observed on the crystal surface after crystal growth was counted with the V/III ratio of the current diffusion layer in growth being changed and the V/III ratio of the intermediate layer in growth being set to 500. As shown in FIG. 3, a number of crystal defects observed on the crystal surface was 20 or less per light emitting diode when the V/III ratio of the current diffusion layer was set to 200 or more.

In the first embodiment, based on the result of the experiment, the V/III ratio of the intermediate layer 15 in growth is set to 500 which is larger than 300, and the V/III ratio of the current diffusion layer 16 in growth is set to 500 which is larger than 200.

Thus, specifying the V/III ratio value of the intermediate layer and the current diffusion layer in growth enhances crystallinity of the intermediate layer and the current diffusion layer to be grown on the light emitting portion, and improves light extraction efficiency and current injection efficiency of the current diffusion layer, thereby enabling provision of high-intensity light emitting diodes. Further, a number of crystal defects observed on the crystal surface after crystal growth may be reduced to 20 or less per light emitting diode, which increases adherence of an electrode, and thereby improves production yield.

(Second Embodiment)

FIG. 4 is a cross sectional view showing a light emitting diode fabricated by a fabrication method of a semiconductor light-emitting device in a second embodiment of the present invention.

As shown in FIG. 4, there are grown in sequence on an n-type GaAs substrate 31, an n-type (AlₓGa₁₋ₓ) _{0.51}In_{0.49}P (0≦x≦1) lower cladding layer 32 (e.g. x=1.0, Si carrier density of 5×10¹⁷cm⁻³, thickness of 1.0 μm), (AlₓGa₁₋ₓ) _{0.51}In_{0.49}P (0≦x≦1) active layer 33 (e.g. x=0.3, thickness of 0.5 μm), and a p-type (AlₓGa₁₋ₓ) _{0.51}In_{0.49}P (0≦x≦1) upper cladding layer 34 (e.g. x=1.0, Zn carrier density of 5×10¹⁷cm⁻³, thickness of 1.0 μm) at a growth rate of approx. 1 to 2.5 μm/h with use of metal-organic chemical vapor deposition (MOCVD) method. The lower cladding layer 32, the active layer 33, and the upper cladding layer 34 constitute a light emitting portion.

Further on top of the light emitting portion, there are grown a p-type (AlₓGa₁₋ₓ) _{y}In_{1-y}P (0≦x≦1, 0≦y<1) intermediate layer 35 (e.g. x=0.4, y=0.9 (lattice match ratio Δa/a against GaAs of approx. −2.8%), Zn carrier density of 1×10¹⁸cm⁻³, thickness of 0.1 μm, growth rate of 0.9 μm/h), and a p-type (AlₓGa₁₋ₓ) _{y}In_{1-y}P (0≦x≦1, 0≦y≦1) current diffusion layer 36 (e.g. x=0.0, y=1.0, Zn carrier density of 3×10¹⁸cm⁻³, thickness of 7.0 μm) with use of metal-organic chemical vapor deposition method. The growth temperature thereof is approx. 730° C.

Next, a p-type electrode 37 (e.g. Au—Zn) is formed on the current diffusion layer 36 by deposition, and an n-type electrode 38 (e.g. Au—Ge) is formed under the n-type GaAs substrate 31 by deposition. Then the p-type electrode 37 is processed to be for example in a round shape, by which a light emitting diode is completed.

In the fabrication method of a semiconductor light-emitting device of the second embodiment, like the first embodiment the intermediate layer 35 has a growth rate of 0.9 μm/h and a lattice match ratio Δa/a against GaAs of −2.8% (satisfying the condition of a growth rate of 1 μm/h or less and the condition of a lattice match ratio Δa/a of −3.2% or more and −2.5% or less). Further, the V/III ratio of the intermediate layer 35 in growth is set to 500 which is larger than 300, and the V/III ratio of the current diffusion layer 36 in growth is set to 500 which is larger than 200, so as to fulfill reduction of a number of crystal defects. However, at the time other than a growth starting time of the intermediate layer 35, the V/III ratio is set to be smaller.

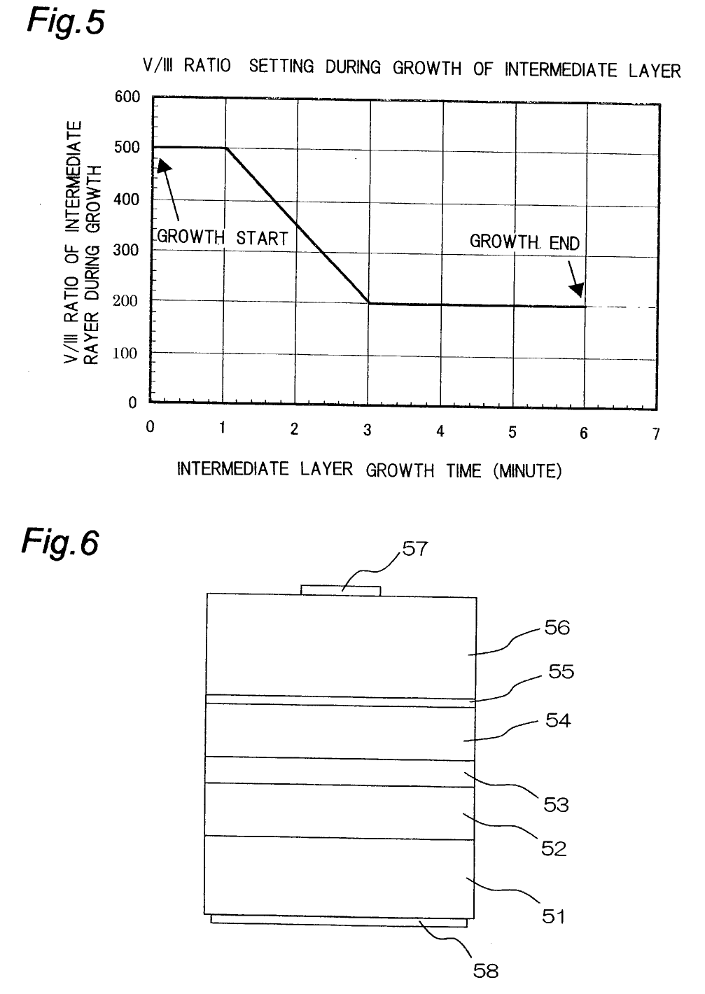

FIG. 5 is a view showing a V/III ratio setting value of the intermediate layer during growth. As shown in FIG. 5, crystal defects are mainly generated at the beginning of the growth. Therefore, the V/III ratio is set high at the beginning of the growth, and thereafter the V/III ratio are declined for reducing consumption of materials, and PH₃ flow is reduced.

As a result, in the fabrication method of a semiconductor light-emitting device of the present invention, crystallinity of the intermediate layer and the current diffusion layer to be grown on the light emitting portion is enhanced, and light extraction efficiency and current injection efficiency of the current diffusion layer are improved, thereby enabling provision of high-intensity light emitting diodes. Further, a number of crystal defects observed on the crystal surface after crystal growth may be reduced to 20 or less per light emitting diode, which increases adherence of an electrode, and thereby improves production yield. In addition, compared to the light emitting diode of the first embodiment, consumption of materials may be reduced, resulting in cost reduction of light emitting diodes.

(Third Embodiment)

FIG. 6 is a cross sectional view showing a light emitting diode fabricated by a fabrication method of a semiconductor light-emitting device in a third embodiment of the present invention.

As shown in FIG. 6, there are grown in sequence on an n-type GaAs substrate 51, an n-type (AlₓGa₁₋ₓ) _{0.51}In_{0.49}P (0≦x≦1) lower cladding layer 52 (e.g. x=1.0, Si carrier density of 5×10¹⁷cm⁻³, thickness of 1.0 μm), (AlₓGa₁₋ₓ) _{0.51}In_{0.49}P (0≦x≦1) active layer 53 (e.g. x=0.3, thickness of 0.5 μm), and a p-type (AlₓGa₁₋ₓ) _{0.51}In_{0.49}P (0≦x≦1) upper cladding layer 54 (e.g. x=1.0, Zn carrier density of 5×10¹⁷cm⁻³, thickness of 1.0 μm) at a growth rate of approx. 1 to 2.5 μm/h with use of metal-organic chemical vapor deposition (MOCVD) method. The lower cladding layer 52, the active layer 53, and the upper cladding layer 54 constitute a light emitting portion.

Further on top of the light emitting portion, there are grown a p-type (AlₓGa₁₋ₓ) _{y}In_{1-y}P (0≦x≦1, 0≦y≦1) intermediate layer 55 (e.g. x=0.4, y=0.9 (lattice match ratio Δa/a against GaAs of approx. −2.8%), Zn carrier density of 1×10¹⁸cm⁻³, thickness of 0.1 μm, growth rate of 0.9 μm/h), and a p-type (AlₓGa₁₋ₓ) _{y}In_{1-y}P (0≦x≦1, 0≦y≦1) current diffusion layer 56 (e.g. x=0.0, y=1.0, Zn carrier density of 3×10¹⁸cm⁻³, thickness of 7.0 μm) with use of metal-organic chemical vapor deposition method. The growth temperature thereof is approx. 730° C.

Next, a p-type electrode 57 (e.g. Au—Zn) is formed on the current diffusion layer 56 by deposition, and an n-type electrode 58 (e.g. Au—Ge) is formed under the n-type GaAs substrate 51 by deposition. Then the p-type electrode 57 is processed to be for example in a round shape, by which a light emitting diode is completed.

In the fabrication method of a semiconductor light-emitting device of the third embodiment, like the first and second embodiments the intermediate layer 55 has a growth rate of 0.9 μm/h and a lattice match ratio Δa/a against GaAs of −2.8% (satisfying the condition of a growth rate of 1 μm/h or less and the condition of a lattice match ratio Δa/a of −3.2% or more and −2.5% or less). Further, the V/III ratio of the intermediate layer 55 in growth is set to 500 which is larger than 300, and the V/III ratio of the current diffusion layer 56 in growth is set to 500 which is larger than 200. This fulfills reduction of a number of crystal defects on the crystal surface after crystal growth. However, at the time other than a growth starting time of the current diffusion layer 56, the V/III ratio is set to smaller.

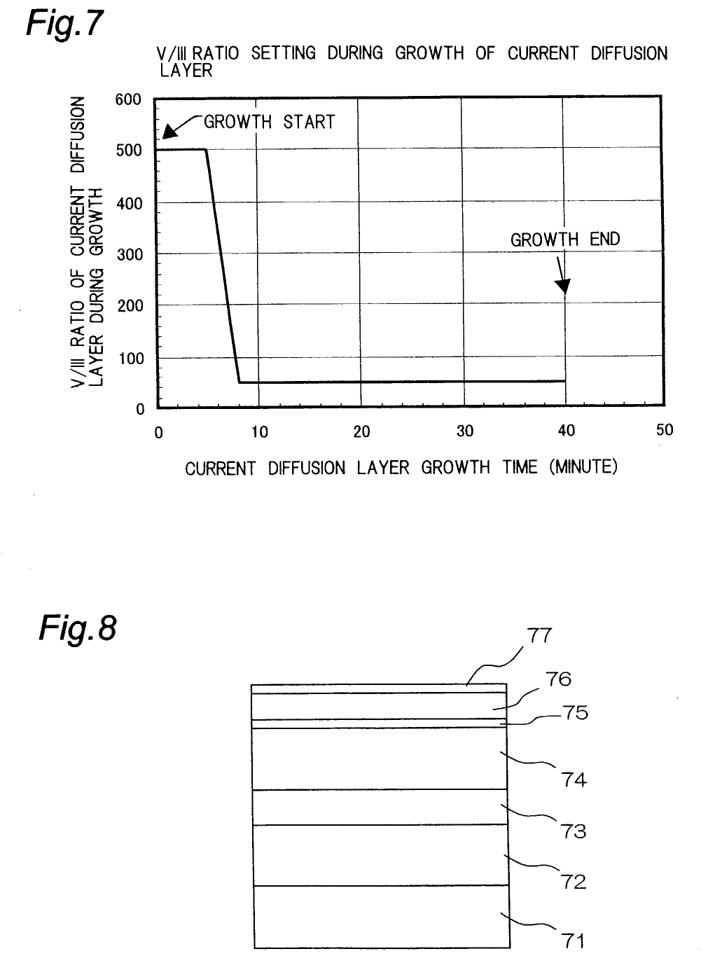

FIG. 7 is a view showing a V/III ratio setting value of the intermediate layer during growth. As shown in FIG. 7, crystal defects are mainly generated at the beginning of the growth. Therefore, the V/III ratio is set high at the beginning of the growth, and thereafter the V/III ratio are declined for reducing consumption of materials, and PH₃ flow is reduced.

As a result, in the fabrication method of a semiconductor light-emitting device in the third embodiment of the present invention, crystallinity of the intermediate layer and the current diffusion layer to be grown on the light emitting portion is enhanced, and light extraction efficiency and current injection efficiency of the current diffusion layer are improved, thereby enabling provision of high-intensity light emitting diodes. Further, a number of crystal defects observed on the crystal surface after crystal growth may be reduced to 20 or less per light emitting diode, which increases adherence of an electrode, and thereby improves production yield. In addition, compared to the light emitting diode of the first embodiment, consumption of materials may be reduced, resulting in cost reduction of light emitting diodes.

(Fourth Embodiment)

FIG. 8 is a cross sectional view showing a light emitting diode fabricated by a fabrication method of a semiconductor light-emitting device in a fourth embodiment of the present invention.

As shown in FIG. 8, there are grown in sequence on an n-type GaAs substrate 71, an n-type (AlₓGa₁₋ₓ) _{0.51}In_{0.49}P (0≦x≦1) lower cladding layer 72 (e.g. x=1.0, Si carrier density of 5×10¹⁷cm⁻³, thickness of 1.0 μm), (AlₓGa₁₋ₓ) _{0.51}In_{0.49}P (0≦x≦1) active layer 73 (e.g. x=0.3, thickness of 0.5 μm), a p-type (AlₓGa₁₋ₓ) _{0.51}In_{0.49}P (0≦x≦1) upper cladding layer 74 (e.g. x=1.0, Zn carrier density of 5×10¹⁷cm⁻³, thickness of 1.0 μm), a p-type (AlₓGa₁₋ₓ) _{y}In_{1-y}P (0≦x≦1, 0≦y≦1) intermediate layer 75 (e.g. x=0.2, y=0.9 (lattice match ratio Δa/a against GaAs of approx. −2.8%), Zn carrier density of 3×10¹⁸cm⁻³, thickness of 0.5 μm), a p-type (AlₓGa₁₋ₓ) _{y}In_{1-y}P (0≦x≦1, 0≦y≦1) first current diffusion layer 76 (e.g. x=0.0, y=1.0, Zn carrier density of 3×10¹⁸cm⁻³, thickness of 1.5 μm), and an n-type (AlₓGa₁₋ₓ) _{y}In_{1-y}P (0≦x≦1, 0≦y≦1) current blocking layer 77 (e.g. x=0.0, y=1.0, Si carrier density of 1×10¹⁸cm⁻³, thickness of 0.3 μm) with use of metal-organic chemical vapor deposition (MOCVD) method. The lower cladding layer 72, the active layer 73, and the upper cladding layer 74 constitute a light emitting portion.

In fabricating the light emitting diode, a growth rate of the intermediate layer 75 and the first current diffusion layer 76 is set as follows.

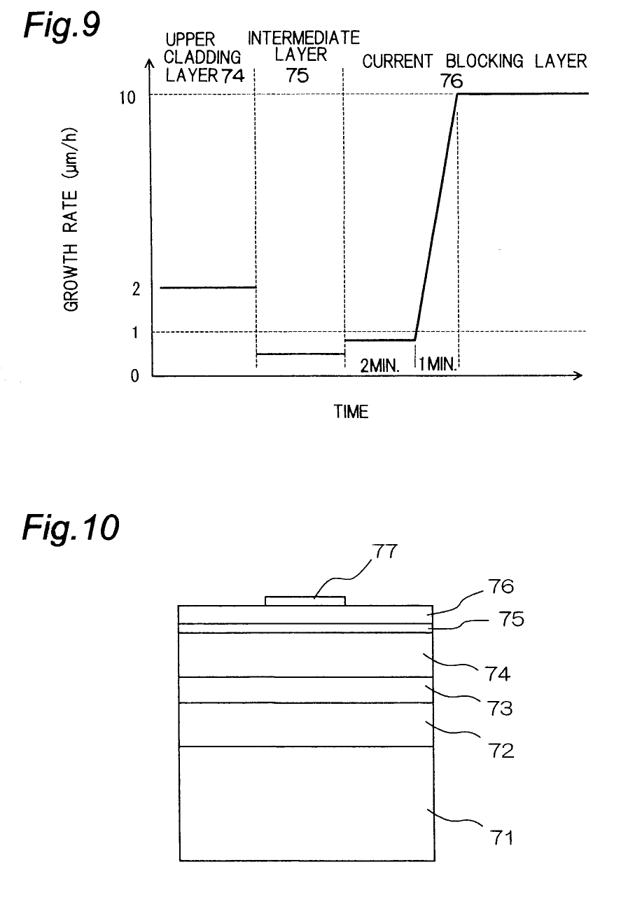

As shown in FIG. 9, the upper cladding layer 74 is grown at a rate of, for example, 2 μm/h, and then the intermediate layer 75 is grown at a rate of 1 μm/h or less (e.g. 0.5 μm/h). Thereafter, the first current diffusion layer 76 is started to be grown at a rate of 1 μm/h or less (e.g. 0.8 μm/h), and is kept on growing for a while (e.g. for around 2 minutes). After that, the growth rate thereof is increased to, for example, 10 μm/h in one minutes, and the first current diffusion layer 76 is kept on growing at the rate of 10 μm/h till the end of the growth.

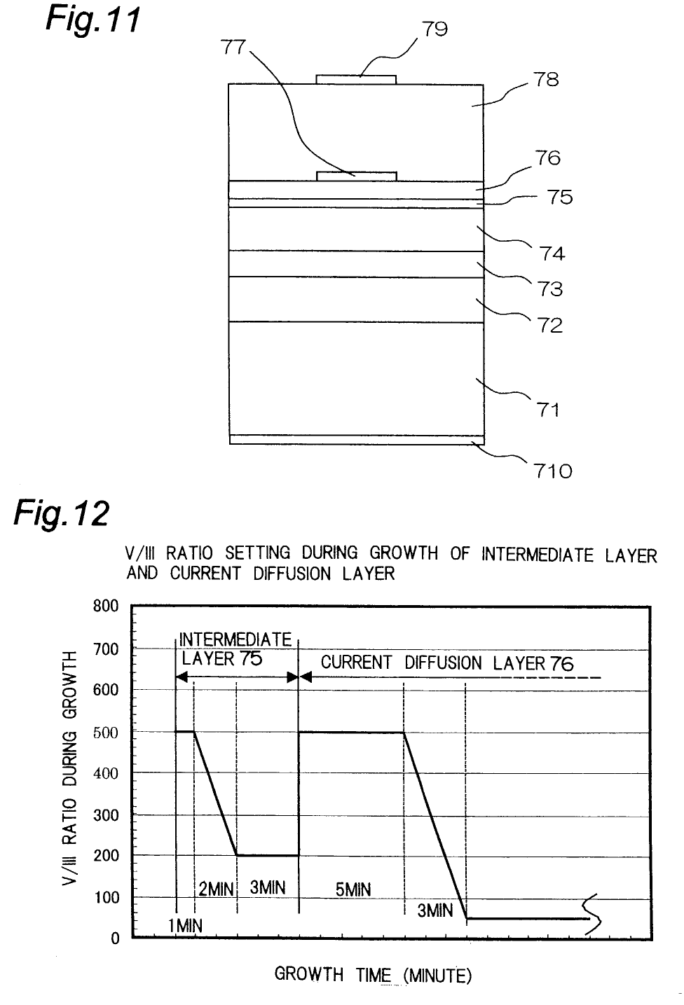

Next as shown in FIG. 10, the current blocking layer 77 is etched into, for example, a round shape with use of a typical photolithography technique. Then, thereon, a p-type (AlₓGa₁₋ₓ) _{y}In_{1-y}P (0≦x≦1, 0≦y≦1) second current diffusion layer 78 (e.g. x=0.0, y=1.0, Zn carrier density of 3×10¹⁸cm⁻³, thickness of 7.0 μm) is grown as shown in FIG. 11.

Then, a p-type electrode 79 (e.g. Au—Zn) is formed on the current diffusion layer 78 by deposition, and an n-type electrode 710 (e.g. Au—Ge) is formed under the n-type GaAs substrate 71 by deposition. Then the p-type electrode 79 is processed to be for example in a round shape, by which a light emitting diode is completed.

In this fourth embodiment, the growth rate of the intermediate layer 75 is set to 0.5 μm/h which is smaller than 1 μm/h, and the growth rate of the first current diffusion layer 76 is also set to 1 μm/h or less, so that a number of crystal defects observed on the crystal surface after crystal growth may be reduced. In addition, setting the lattice match ratio Δa/a of the intermediate layer 75 against GaAs to −2.8% also contributes to reduction of a number of crystal defects (satisfying the condition of a lattice match ratio Δa/a of −3.2% or more and −2.5% or less).

Furthermore, the V/III ratio of the intermediate layer 75 in growth is set to 500 which is larger than 300 at the beginning of the growth, and the V/III ratio of the current diffusion layer 76 in growth is set to 500 which is larger than 200 at the beginning of the growth, so as to decrease a number of crystal defects. However, at the time other than the growth starting time of the intermediate layer 75 and the current diffusion layer 76, the V/III ratio is set to smaller.

FIG. 12 is a view showing a V/III ratio setting value of an intermediate layer and a current diffusion layer during growth. As shown in FIG. 12, crystal defects are mainly generated at the beginning of the growth. Therefore, the V/III ratio is set high at the beginning of the growth, and thereafter the V/III ratio are declined for reducing consumption of materials, and PH₃ flow is reduced.

As a result, in the fabrication method of a semiconductor light-emitting device in the fourth embodiment of the present invention, crystallinity of the intermediate layer and the current diffusion layer to be grown on the light emitting portion is enhanced, and light extraction efficiency and current injection efficiency of the current diffusion layer are improved, thereby enabling provision of high-intensity light emitting diodes. Further, a number of crystal defects observed on the crystal surface after crystal growth may be reduced to 20 or less per light emitting diode, which increases adherence of an electrode, and thereby improves production yield. In addition, compared to the light emitting diodes of the first to the third embodiments, consumption of materials may be reduced, resulting in cost reduction of light emitting diodes.

(Fifth Embodiment)

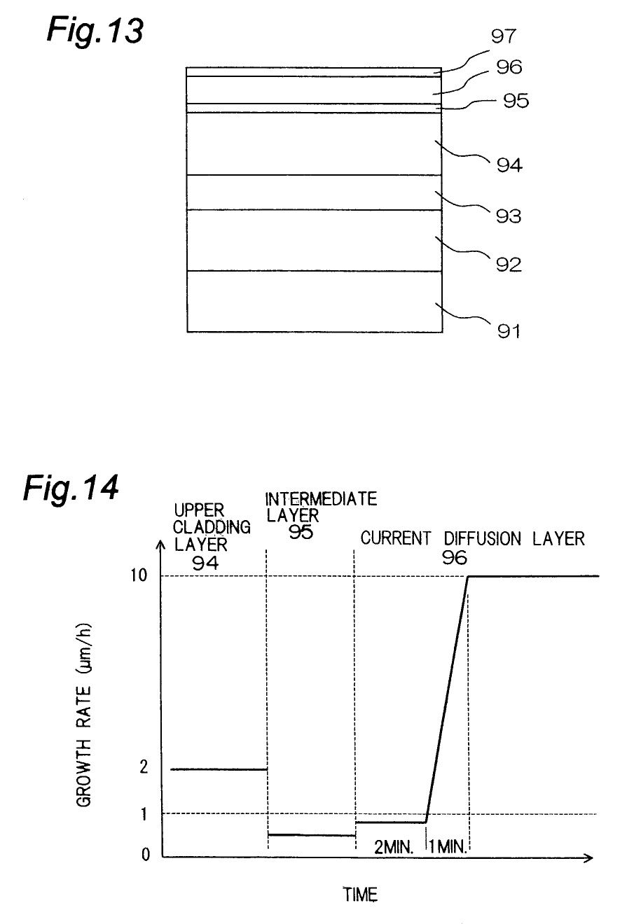

FIG. 13 is a cross sectional view showing main part of a light emitting diode fabricated by a fabrication method of a semiconductor light-emitting device in a fifth embodiment of the present invention.

As shown in FIG. 13, there are grown in sequence on an n-type GaAs substrate 91, an n-type (AlₓGa₁₋ₓ) _{0.51}In_{0.49}P (0≦x≦1) lower cladding layer 92 (e.g. x=1.0, Si carrier density of 5×10¹⁷cm⁻³, thickness of 1.0 μm), (AlₓGa₁₋ₓ) _{0.51}In_{0.49}P (0≦x≦1) active layer 93 (e.g. x=0.3, thickness of 0.5 μm), a p-type (AlₓGa₁₋ₓ) _{0.51}In_{0.49}P (0≦x≦1) upper cladding layer 94 (e.g. x=1.0, Zn carrier density of

5×10¹⁷cm⁻³, thickness of 1.0 μm), a p-type (AlₓGa₁₋ₓ) _{y}In_{1-y}P (0≦x≦1, 0≦y≦1) intermediate layer 95 (e.g. x=0.5, y=0.9 (lattice match ratio Δa/a against GaAs of approx. −2.8%), Zn carrier density of 3×10¹⁸cm⁻³, thickness of 0.5 μm), a p-type (AlₓGa₁₋ₓ) _{y}In_{1-y}P (0≦x≦1, 0≦y≦1) first current diffusion layer 96 (e.g. x=0.0, y=1.0, Zn carrier density of 3×10¹⁸cm⁻³, thickness of 1.5 μm), and an n-type (AlₓGa₁₋ₓ) _{y}In_{1-y}P (0≦x≦1, 0≦y≦1) current blocking layer 97 (e.g. x=0.0, y=1.0, Si carrier density of 1×10¹⁸cm⁻³, thickness of 0.3 μm) with use of metal-organic chemical vapor deposition (MOCVD) method. The lower cladding layer 92, the active layer 93, and the upper cladding layer 94 constitute a light emitting portion.

In fabricating the light emitting diode, a growth rate of the intermediate layer 95 and the first current diffusion layer 96 is set as follows.

As shown in FIG. 14, the upper cladding layer 94 is grown at a rate of, for example, 2 μm/h, and then the intermediate layer 95 is grown at a rate of 1 μm/h or less (e.g. 0.5 μm/h). Thereafter, the first current diffusion layer 96 is started to be grown at a rate of 1 μm/h or less (e.g. 0.8 μm/h), and is kept on growing for a while (e.g. for around 2 minutes). After that, the growth rate thereof is increased to, for example, 10 μm/h in one minutes, and the first current diffusion layer 76 is kept on growing at the rate of 10 μm/h till the end of the growth.

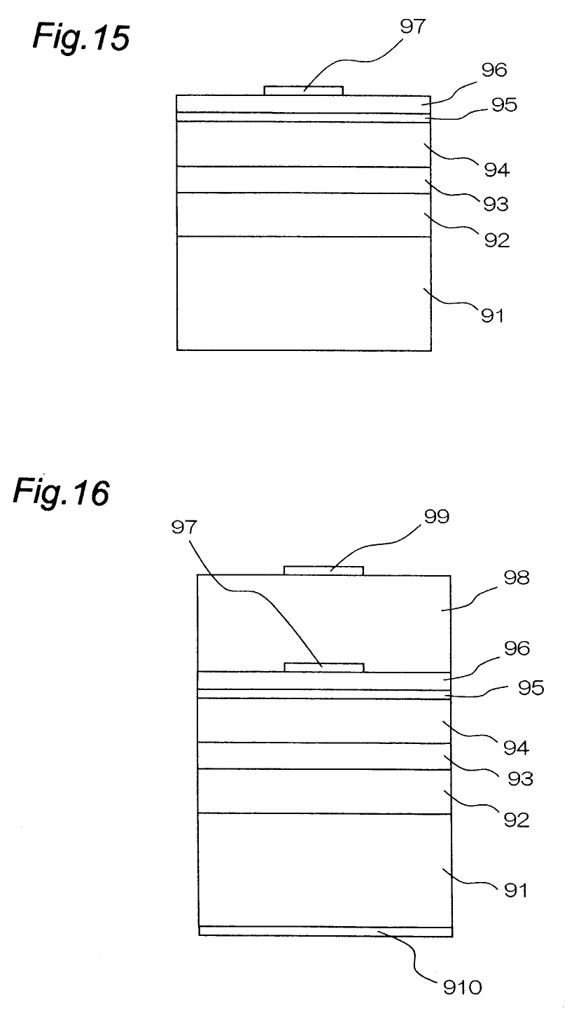

Next as shown in FIG. 15, the current blocking layer 97 is etched into, for example, a round shape with use of a typical photolithography technique. Then, thereon, a p-type (AlₓGa₁₋ₓ) _{y}In_{1-y}P (0≦x≦1, 0≦y≦1) second current diffusion layer 98 (e.g. x=0.0, y=1.0, Zn carrier density of 3×10¹⁸cm⁻³, thickness of 7.0 μm) is grown as shown in FIG. 16.

Then, a p-type electrode 99 (e.g. Au—Zn) is formed on the second current diffusion layer 98 by deposition, and an n-type electrode 910 (e.g. Au—Ge) is formed under the n-type GaAs substrate 91 by deposition. Then the p-type electrode 99 is processed to be for example in a round shape, by which a light emitting diode is completed.

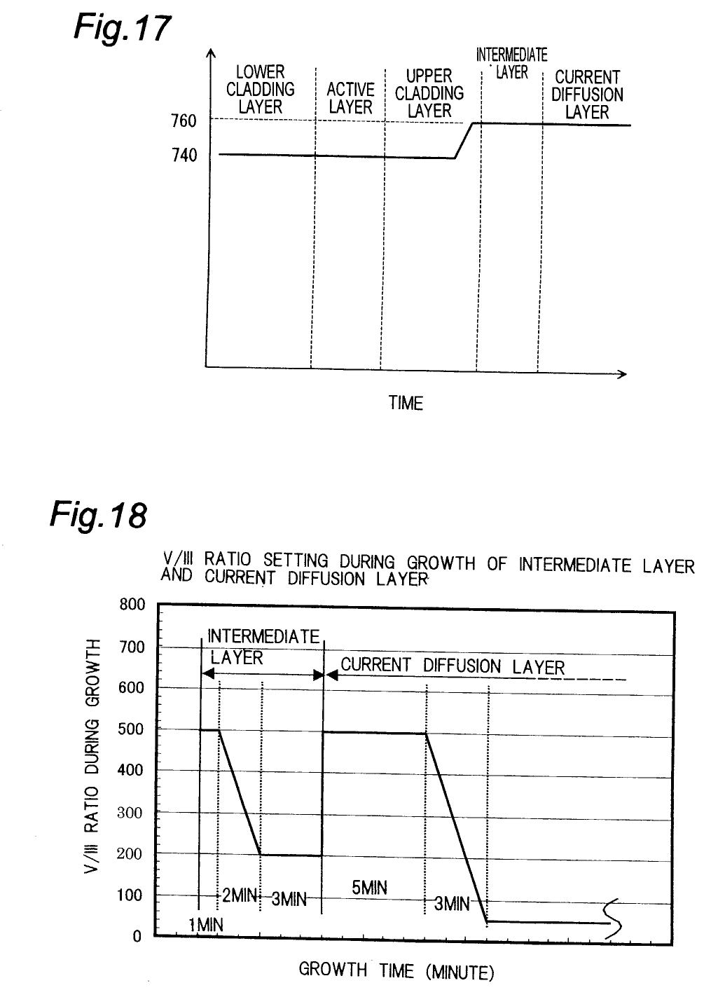

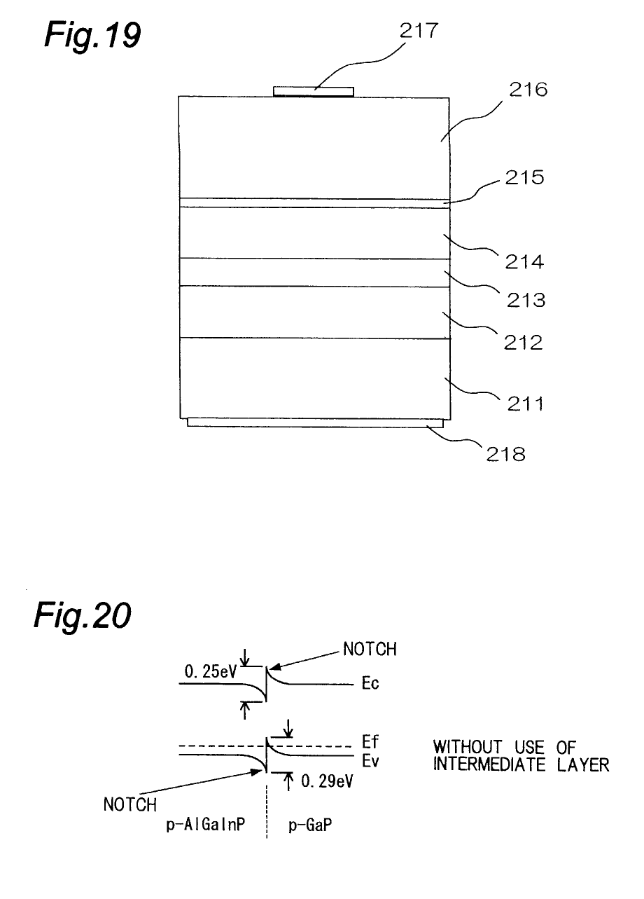

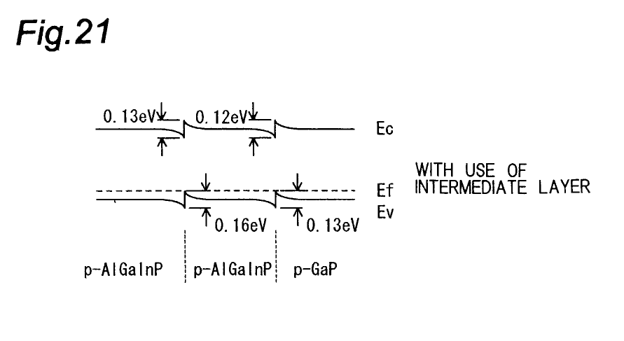

In this fifth embodiment, the growth rate of the intermediate layer 95 is set to 0.5 μm/h which is smaller than 1 μm/h, and the growth rate of the first current diffusion layer 96 is also set to 1 μm/h or less, so that a number of crystal defects observed on the crystal surface may be reduced. In addition, setting the lattice match ratio Δa/a of the intermediate layer 95 against GaAs to −2.8% also contributes to reduction of a number of crystal defects (satisfying the condition of a lattice match ratio Δa/a of −3.2% or more and −2.5% or less). Further in the fifth embodiment, a growth temperature is raised in the middle of the growth of the upper cladding layer 94, thereby making the growth temperature of the intermediate layer 95 and the layers thereon higher than the growth temperature of the active layer 93 as shown in FIG. 17. This also implements reduction of a number of crystal defects.

Furthermore, the V/III ratio of the intermediate layer 95 in growth is set to 500 which is larger than 300 at the beginning of the growth, and the V/III ratio of the current diffusion layer 96 in growth is set to 500 which is larger than 200 at the beginning of the growth, so as to decrease a number of crystal defects. However, at the time other than the growth starting time of the intermediate layer 95 and the current diffusion layer 96, the V/III ratio is set to smaller.

FIG. 18 is a view showing a V/III ratio setting value of an intermediate layer and a current diffusion layer during growth. As shown in FIG. 18, crystal defects are mainly generated at the beginning of the growth. Therefore, the V/III ratio is set high at the beginning of the growth, and thereafter the V/III ratio is declined for reducing consumption of materials, and PH₃ flow is reduced.

As a result, in the fabrication method of a semiconductor light-emitting device in the fifth embodiment of the present invention, crystallinity of the intermediate layer and the current diffusion layer to be grown on the light emitting portion is enhanced, and light extraction efficiency and current injection efficiency of the current diffusion layer are improved, thereby enabling provision of high-intensity light emitting diodes. Further, a number of crystal defects observed on the crystal surface after crystal growth may be reduced to 20 or less per light emitting diode, which increases adherence of an electrode, and thereby improves production yield. In addition, compared to the light emitting diodes of the first to the third embodiments, consumption of materials may be reduced, resulting in cost reduction of light emitting diodes.

It would be understood that the fabrication method of a semiconductor light-emitting device of the present invention is not limited to the-above described embodiments. Although in the first to the fifth embodiments, the light emitting portion is composed of AlGaInP semiconductor, semiconductor light-emitting devices made from other materials may be embodied in the present invention if the contents of the function and operations of each layer are identical to those of the present invention. Similarly, a material and a composition ratio of other layers may be modified within the range of implementing an intended effect.

Also in the first to the fifth embodiments, the current diffusion layer and the current blocking layer are used as a layer to be grown on the upper cladding layer or as a layer to be grown on the intermediate layer. However, the present invention is applicable to the semiconductor light-emitting devices including other layers such as protection layers and etch-stop layers.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A fabrication method of a semiconductor light-emitting device having a light emitting portion composed of at least a lower cladding layer, an active layer, and an upper cladding layer formed on a compound semiconductor substrate, and a layer to be grown above the light emitting portion, characterized in that
lattice mismatch with 0.25% or more absolute value of a lattice match ratio Δa/a is present in between a layer grown above the light emitting portion and a layer grown right under the light emitting layer, and at least at a growth starting time of the layer to be grown above the light emitting portion, a V/III ratio that is a ratio of a molar flow rate of feeding V-group material gas to a molar flow rate of feeding III-group material gas is so set that a number of crystal defects observed on a crystal surface at an end of growth of all crystals in the semiconductor light-emitting device is to be 20 or less per semiconductor light-emitting device.

2. The fabrication method of a semiconductor light-emitting device as defined in claim 1, wherein
the layer to be grown above the light emitting portion includes an intermediate layer for alleviating at least either lattice mismatch or energy discontinuity between a layer to be grown further above and the light emitting portion.

3. The fabrication method of a semiconductor light-emitting device as defined in claim 1, wherein
the layer to be grown above the light emitting portion includes at least either a current diffusion layer or a current blocking layer.

4. The fabrication method of a semiconductor light-emitting device as defined in claim 2, wherein
the compound semiconductor substrate is composed of GaAs, and
the lower cladding layer, the active layer, the upper cladding layer, and the layer to be grown above the light emitting portion are composed of (AlₓGa₁₋ₓ) _{y}In_{1-y}P (0≦x≦1, 0≦y≦1) semiconductor.

5. A fabrication method of a semiconductor light-emitting device having a light emitting portion composed of at least a lower cladding layer, an active layer, and an upper cladding layer formed on a compound semiconductor substrate,
an intermediate layer to be grown on the upper cladding layer in the light emitting portion, and
at least either a current diffusion layer or a current blocking layer to be grown on the intermediate layer,
the intermediate layer alleviating at least either lattice mismatch or energy discontinuity between the current diffusion layer and the light emitting portion or between the current blocking layer and the light emitting portion, characterized in that
the lower cladding layer, the active layer, the upper cladding layer, and the intermediate layer are composed of (AlₓGa₁₋ₓ) _{y}In_{1-y}P (0≦x≦1, 0≦y≦1) semiconductor,
the current diffusion layer or the current blocking layer are composed of (AlₓGa₁₋ₓ) _{y}In_{1-y}P (0≦x≦1, 0≦y≦1) semiconductor, and
at least at a growth starting time in growing the intermediate layer on the upper cladding layer with presence of lattice mismatch against the upper cladding layer with 0.25% or more absolute value of a lattice match ratio Δa/a, a V/III ratio that is a ratio of a molar flow rate of feeding V-group material gas to a molar flow rate of feeding III-group material gas is set to be 300 or more.

6. A fabrication method of a semiconductor light-emitting device having a light emitting portion composed of at least a lower cladding layer, an active layer, and an upper cladding layer formed on a compound semiconductor substrate,
an intermediate layer to be grown on the upper cladding layer in the light emitting portion, and
at least either a current diffusion layer or a current blocking layer to be grown on the intermediate layer,
the intermediate layer alleviating at least either lattice mismatch or energy discontinuity between the current diffusion layer and the light emitting portion or between the current blocking layer and the light emitting portion, characterized in that
the lower cladding layer, the active layer, the upper cladding layer, and the intermediate layer are composed of (AlₓGa₁₋ₓ) _{y}In_{1-y}P (0≦x≦1, 0≦y≦1) semiconductor,
the current diffusion layer or the current blocking layer is composed of (AlₓGa₁₋ₓ) _{y}In_{1-y}P (0≦x≦1, 0≦y≦1) semiconductor, and
in growing the current diffusion layer or the current blocking layer on the intermediate layer with presence of lattice mismatch against the intermediate layer with 0.25% or more absolute value of a lattice match ratio Δa/a, a V/III ratio that is a ratio of a molar flow rate of feeding V-group material gas to a molar flow rate of feeding III-group material gas at least at a growth starting time of the current diffusion layer or the current blocking layer is set to be 200 or more.

7. The fabrication method of a semiconductor light-emitting device as defined in claim 1, wherein
during growth after a growth starting time in a growing process of the layer to be grown above the light emitting portion, a V/III ratio that is a ratio of a molar flow rate of feeding V-group material gas to a molar flow rate of feeding III-group material gas is set to be smaller than that at the growth starting time.

8. The fabrication method of a semiconductor light-emitting device as defined in claim 1, wherein
a growth rate at least at a growth starting time of the layer to be grown above the light emitting portion is 1 μm/h or less.

9. The fabrication method of a semiconductor light-emitting device as defined in claim 2, wherein
the intermediate layer is composed of AlGaInP semiconductor having a lattice match ratio Δa/a against GaAs of −3.2% or more and −2.5% or less.

10. The fabrication method of a semiconductor light-emitting device as defined in claim 1, wherein
a growth temperature of the layer to be grown above the light emitting portion is higher than a growth temperature of the active layer.

11. The fabrication method of a semiconductor light-emitting device as defined in claim 1, wherein
MOCVD (metal-organic chemical vapor deposition) method is used to grow the lower cladding layer, the active layer, the upper cladding layer, and the layer to be grown above the light emitting portion.
